(19) United States
(12) Patent Application Publication
(10) Pub. No.: US 2004/0130863 A1
(43) Pub. Date: Jul. 8, 2004

(54) Method and apparatus for mounting electronic components and program therefor

(75) Inventors: Kouji Shimizu, Chiryu-shi (JP); Seiichi Terui, Chiryu-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Fuji Machine Mfg. Co., Ltd., Chiryu-shi (JP)

(21) Appl. No.: 10/669,552

(22) Filed: Sep. 25, 2003

(30) Foreign Application Priority Data
Sep. 25, 2002 (JP) 2002-280087

(51) Int. Cl. H05K 5/00

(52) U.S. Cl. 361/683

(57) ABSTRACT

Disclosed is an electronic component mounting apparatus, which is provided with a board transfer device for transferring circuit boards and a pair of component supply devices arranged with the board transfer device therebetween for supplying electronic components on the boards. Of the component supply devices, one of them is designated as main component supply device for primarily supplying the electronic components on the boards, and the other is designated as secondary component supply device for supplying the electronic components as long as the component supply from the main component supplying device is discontinued. The electronic component mounting apparatus performs a switching control so that the electronic components are supplied from the main component supply device during the ordinary mounting operation, but from the secondary component supply device when th component supply from the main component supplying device is discontinued.

### INCORPORATION BY REFERENCE

This application is based on and claims priority under 35 U.S.C. sctn, 119 with respect to Japanese Application No. 2002-280087 filed on Sep. 25, 2002, the entire content of which is incorporated herein by reference.

### BACKGROUND OF THE INVENTION

1. Field of the Invention

The present invention relates to an electronic component mounting method of mounting electronic components on circuit boards and particularly, to a method of supplying the electronic components. It also relates to an electronic component mounting apparatus for mounting electronic components on circuit boards and particularly, to a component supply system for supplying the electronic components. It further relates to an electronic component mounting program for controlling the mounting of electronic components on circuit boards and particularly, to a program for controlling the supply of the electronic components.

2. Discussion of the Related Art

As electronic component mounting apparatus of this kind, there has been known an apparatus of the construction shown in FIG. 8. In the known electronic component mounting apparatus, component supply devices 2, 3 for supplying electronic components onto circuit boards have been arranged having therebetween a board transfer device 1 for transferring the boards. Each of the component supply devices 2, 3 includes two units 2a, 2b, 3a, 3b each composed of a plurality of component supply cassettes.

For example, electronic components of plural kinds which are necessary to be mounted on circuit boards (A) are set assorted in the units 2a and 3a, and electronic components of plural kinds which are necessary to be mounted on the boards (A) and which are the same as those in the unit 2a and 3a are also set assorted in the units 2b and 3b. In mounting the components on the boards in the known electronic component mounting apparatus, the components are first supplied from the units 2a, 3a to be mounted on the boards. Then, at the shortage of the components in the units 2a, 3a, the supply of the components from the units 2a, 3a is halted, and instead, the components are supplied from the units 2b, 3b. During this time, the worker removes the units 2a, 3a, charges or replenishes the same with the components and upon completion of the replenishment, attaches the units 2a, 3a as they were. Thereafter, the supply of the components from the units 2b, 3b is halted, and the supply of the components from the unit 2a, 3a is resumed for mounting operations.

In replenishing the components in the foregoing electronic component mounting apparatus, the worker (M) removes either one of the units 2a, 3a which are arranged at opposite sides of the component mounting apparatus to replenish the removed unit with the components and thereafter, removes the remaining unit to replenish the same with the components. That is, the worker (M) is forced to remove the unit twice laboriously for component replenishment. In addition, he has to come and go between the both sides of the mounting apparatus, which gives rise to a problem in terms of being time consuming. In particular, where two or more electronic mounting apparatus are arranged closely in series or tandem thereby to constitute a long mounting line, a much longer time has to be taken disadvantageously for th worker to go and back between the both sides of each mounting apparatus.

### SUMMARY OF THE INVENTION

It is therefore a primary object of the present invention to provide an improved method and apparatus which is capable of making the worker easer in charging or replenishing component supply devices with electronic components Another object of the present invention is to provide an improved method and apparatus which is capable of continuing the mounting operations of electronic components on circuit boards successively transferred by a component transfer device.

Briefly, in a method and apparatus according to the present invention, electronic components are supplied from both of a pair of component supply devices which are arranged with a board transfer device therebetween, and are mounted on boards transferred by the board transfer device. The method and apparatus comprises a step and means for designating one of the component supply devices as a main component supply device for primarily supplying the components and the other component supply device as a sub or secondary component supply device for supplying the components while the supply of the component from the main component supply device is discontinued. The method and apparatus further comprises another step and means for supplying the components from the main component supply device during an ordinary mounting operation, and when the supply of the component from the main component supply device is discontinued, for performing a switching control so that the components are then supplied from the secondary component supply device.

With the aforementioned configuration, when the supply of the components from the main component supply device is discontinued while the electronic component mounting apparatus is in operation to mount the electronic components from the main component supply device, an automatic switching control is performed to halt the supply from the main component supply device and instead, to start th supply from the secondary component supply device, during which the worker charges or replenishes the main component supply device with the components. In this replenishment, he or she is required only to replenish the main component supply device, i.e., one of the component supply devices, but not required to replenish both of the component supply devices, as is the case in the prior art. Accordingly, the worker can be relieved of a heavy work in replenishing the both of the component supply devices with the components in a hurry, and the replenishment of the components can be changed to the work to easer to do.

### BRIEF DESCRIPTION OF THE ACCOMPANYING DRAWINGS

The foregoing and other objects and many of the attendant advantages of th present invention may readily be appreciated as the same becomes better understood by reference to the following preferred embodiments of the present invention when considered in connection with the accompanying drawings, wherein like reference numerals designate the same or corresponding components throughout several views, and in which:

FIG. 1 is a plan view of an electronic component mounting apparatus incorporating a board transfer device and components supply devices;

FIG. 2 is a block diagram showing the configuration of an electric control circuit of the electronic component mounting apparatus;

FIG. 3 is a flow chart of a control program which a controller shown in FIG. 2 executes in the first embodiment;

FIG. 4 is a flow chart of another control program executed by the controller in the second embodiment;

FIG. 5 is a flow chart of a further control program executed by the controller in the third embodiment;

FIG. 6 is a flow chart of still another control program executed by th controller in the fourth embodiment;

FIG. 7(A) is a plan view showing the electronic component mounting apparatus of a modified form wherein for mounting on a small board, the transfer guide way is arranged closely to a main component supply device, and FIG. 7(B) is another plan view showing the mounting apparatus of another modified form wherein for mounting on the small board, the transfer guide way is arranged closely to a sub or secondary component supply device, and

FIG. 8 is a plan view of an electronic component mounting apparatus in the prior art incorporating a board transfer device and component supply devices.

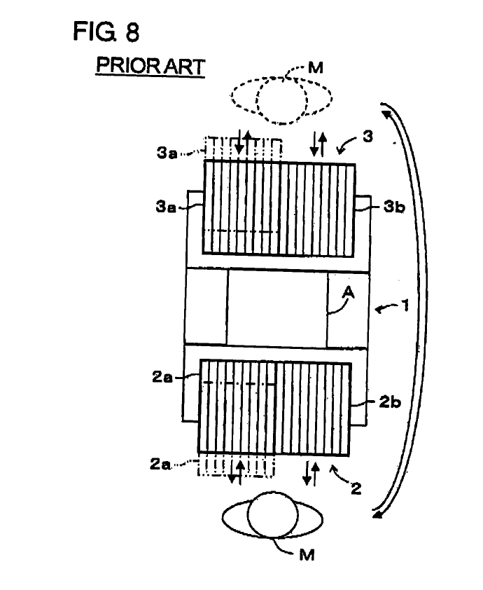

### DETAILED DESCRIPTION OF PREFERRED EMBODIMENTS

The first embodiment of an electronic component mounting apparatus according to the present invention will be described hereinafter with reference to the accompanying drawings.

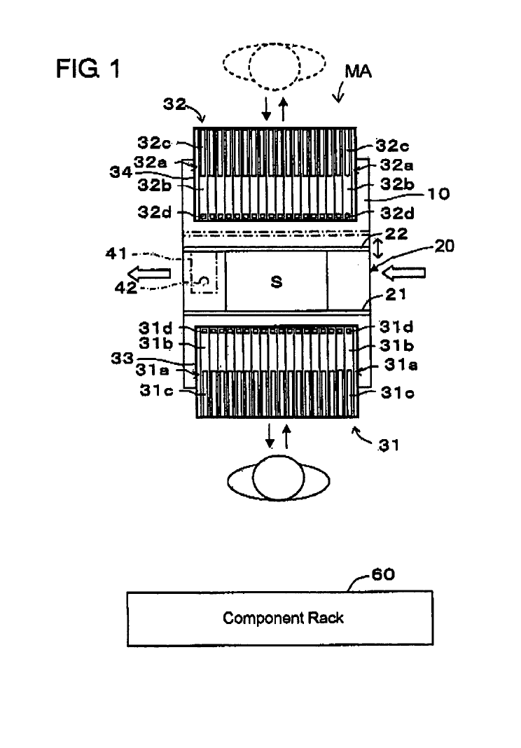

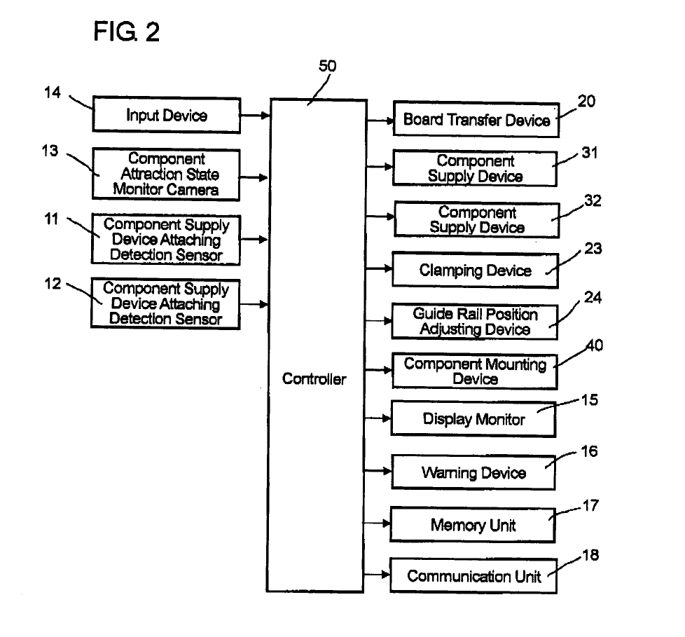

FIG. 1 is a plan view of an electronic component mounting apparatus incorporating a board transfer device and components supply devices, and FIG. 2 is a block diagram showing the configuration of an electric control circuit for th electronic components mounting apparatus. The following description will be mad showing an example wherein a large volume production is to be performed for component mounting boards of the same kind each of which is not so many in the number of electronic components to be mounted thereon.

As shown in FIG. 1, the electronic component mounting apparatus MA is provided with those components mounted on a base frame 10 which comprise a board transfer device 20 for transferring circuit boards (preferably, printed-circuit boards) (S) successively, a pair of component supply devices 31, 32 disposed with the board transfer device 20 therebetween for supplying electronic components to be mounted on each of the board (S), and a component mounting device 40 (not shown in FIG. 1, but designated in FIG. 2) arranged over the board transfer device 20 and over the both of the component supply devices 31, 32. The mounting device 40 is automatically operable for sucking and holding on a mounting head 41 at a time one or more electronic components supplied from both of the component supply devices 31, 32 and for mounting the electronic components one after another on the board (S) supported on the board transfer device 20, The board transfer device 20 is for transferring the boards (S) in a predetermined direction (toward the left in FIG. 1) and is provided with first and second guide rails 21, 22 mounted on the base frame 10. The first and second guide rails 21, 22 extend in the transfer direction and in parallel relation with each other for guiding the boards (S) in the transfer direction. Further, the transfer device 20 is provided with a pair of endless conveyor belts (not shown) which circulate respectively beneath the first and second guide rails 21, 22 in parallel with the same and with each other. These conveyor belts carry and transfer the boards (S) in the transfer direction. Thus, when the conveyor belts are driven by a belt drive device (not shown), the boards (S) carried on the pair of the conveyor belts are guided along the guide rails 21, 22 to be transferred in the transfer direction.

Each circuit board (S), when loaded and transferred to a predetermined potion as shown in FIG. 1, is lifted up by a clamping device 23 against the guide rails 21, 22, so that it can be clamped to be fixedly positioned thereat.

As shown in FIG. 1, the component supply device 31 houses or accommodates plural cassette-type feeders (component supply cassettes) 31a on a single table 33 in parallel relation. Each cassette-type feeder 31a is composed of a body member 31b removably attached to the table 33, a supply reel 31c and a component take-out port 31d. The supply reel 31c winds and holds a slender tape (not shown) which encloses plural electronic components at a regular pitch or interval. The tape is pulled out by means of a sprocket wheel (not shown) in the regular pitch, and the electronic components are released from being enclosed thereby to be fed successively to the component take-out port 31d.

Like the component supply device 31, as shown in FIG. 1, the other component supply device 32 accommodates plural cassette-type feeders (component supply cassettes) 32a on another single table 34 in parallel relation. Each cassette-type feeder 32a, like the cassette-type feeder 31a, is composed of a body member 32b, a supply reel 32c and a component take-out port 32d.

Further, the first guide rail 21 is fixed close to the component supply device 31 not to be adjustable in position, while the second guide rail 22 is mounted to be adjustable in position in the direction of the width of the transfer way which is constituted together with the first guide rail 21. Thus, a guide rail position adjusting device 24 controls the second guide rail 22 so that the same is moved to a target position depending on the width of any circuit board (S) to be transferred and then, is fixedly positioned.

In this particular embodiment, it is assumed that various electronic components which are necessary to be mounted on a first circuit board (S1) have been set respectively in the respective cassette-type feeders 31a of the component supply device 31 serving as the main component supply device, and that various electronic components which are necessary to be mounted on the first circuit board (S1) and which are the same as those set in the main component supply device 31 have been set in the respective cassette-type feeders 32a of the component supply device 32 serving as the sub or secondary component supply device.

Further, when the electronic components are to be replenished into any of the cassette-type feeders 31a (or 32a) which have been in short of the components, the component supply device 31 (or 32), together with the table 33 (or 34) is first removed from the base frame 10. Then, those cassette-type feeders 31a (or 32a) which have been in short of the components are removed from the table 33 (or 34) and the supply reels 31c (or 32c) of those feeders 31a (or 32a) are replaced with new ones. Subsequently, those cassette-type feeders 31a (or 32a) with which replacements were made are again attached onto the table 33 (or 34), after which th component supply device 31 (or 32), together with the table 33 (or 34) is attached to the base frame 10. In this manner, the removal and attaching of each component supply device 31 (or 32) can be done together with the table 33 (or 34) as a unit.

As shown in FIG. 2, the electronic component mounting apparatus MA is further provided with supply device attaching detection sensors 11, 12 for detecting whether or not, the component supply device 31 or 32 have been attached to respective predetermined positions. Each of the attaching detection sensors 11, 12 is constituted by a mechanical switch such as, e.g., a microswitch, or by an optical sensor such as, e.g., a photo interrupter. Each sensor 11 or 12 is operable for outputting to a controller 50 a signal indicative of the attaching state when the table 33 or 34 for the component supply device 31 or 32 has been attached to the predetermined position or another signal indicative of the non-attaching state when it has been out of the predetermined position.

The component mounting device 40 is provided on an XY robot (not shown) which is mounted on the base frame 10. The device 40 is provided with a mounting head 41 movable by the XY robot in X-axis and Y-axis directions perpendicular to each other and one or more suction nozzles 42 mounted on the mounting head 41 each for attracting an electronic component thereto to mount the same at a target position on the board (S). The component mounting device 40 picks up one or more electronic components from the take-out ports 31d (or 32d) of one or more cassette-type feeders 31a (or 32a) and mounts them at designated target positions on the board (S).

The electronic component mounting apparatus MA is also provided with a component attraction state monitor camera 13 on the base frame 10. The camera 13 monitors the states of the electronic components being sucked to the suction nozzles 42 carried on the mounting head 41. As described later, the controller 50 inputs image data depicting the states of the electronic components being monitored by the monitor camera 13.

The electronic component mounting apparatus MA is further provided with an input device 14, which inputs a mounting start command, a mounting stop command and a main/secondary device designation command. In inputting the main/secondary device command, the input device 14 designates either one of the component supply devices 31, 32 as the main component supply device which primarily serves to supply the electronic components and also designates the other supply device as the secondary component supply device which is enabled to supply the electronic components after the supply of the component from the main component supply device is discontinued. The input device 14 is composed of switches of various kinds and a numeric keypad. The aforementioned data and the designation information are input by the manipulation of the input device 14 to the controller 50.

The keyboard as used in personal computers may be employed as the input device 14, or it may be employed as that displayed on an LCD screen of a well-known touch panel type. Also, for the purpose of designating the aforementioned main and secondary component supply devices, the input device 14 may be provided with a dedicated switch or any existing switch for giving a certain command or a numeric keypad may be employed for this purpose.

The controller 50 is connected to the board transfer device 20, the pair of component supply devices 31, 32, the clamping device 23, the guide rail position adjusting device 24, and the component mounting device 40. Based on signals, data and information which are input from the input device 14, the component holding state monitor camera 13, and the supply device attaching detection sensors 11, 12, the controller 50 controls the operations of the board transfer device 20, the pair of component supply devices 31, 32, the clamping device 23, the guide rail position adjusting device 24, and the component mounting device 40.

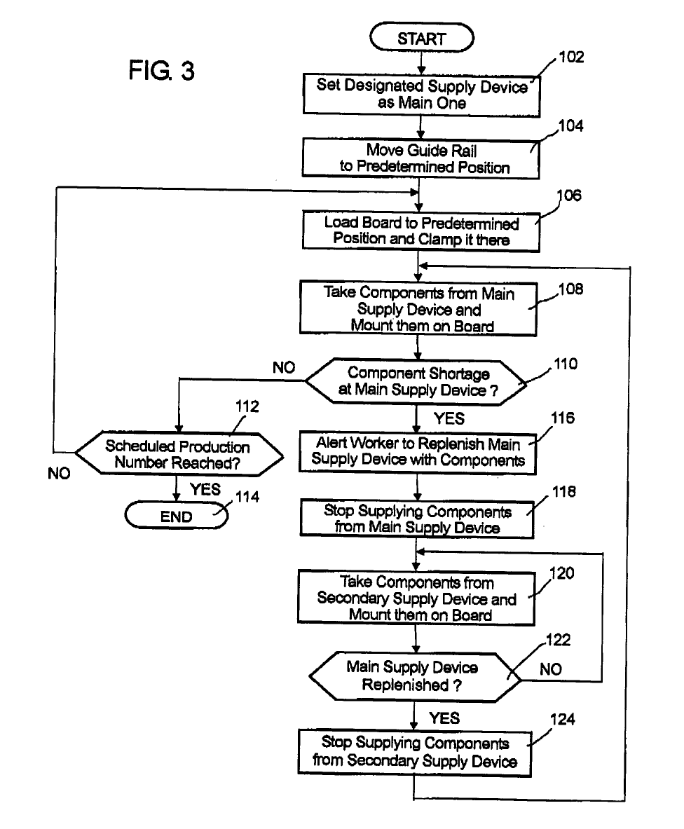

The controller 50 incorporates a microcomputer (not shown) therein, which has input/output interfaces, a CPU, a RAM and a ROM (all now shown) each connected thereto through bus lines. The CPU executes a mounting control program represented by a flow chart shown in FIG. 3 for controlling the mountings of electronic components onto the boards (S). Particularly, in the ordinary mounting operation, the CPU controls the component supply device 31 (or 32) to supply electronic components. On the other hand, in the event that the component supply device 31 (or 32) runs short of electronic components to supply, the CPU executes such a switching control as to cease supplying the components from the component supply device 31 (or 32) and instead, to initiate supplying the components from the component supply device 32 (or 31). The RAM temporally stores variables necessary for the CPU to execute the mounting control program, and the ROM has stored the program in advance.

The controller 50 also has connected thereto a memory unit 17, which stores data necessary to control the electronic component mounting apparatus MA in the concrete, the memory unit 17 has stored data input from peripheral devices (not shown) through a communication unit 18 in relation to the electronic components to be mounted onto the boards (S), data on the boards (S) such as, e.g., the coordinates of target positions onto which the electronic components are to be mounted and the like, scheduled numbers of the boards to be produced, and the identification of the component supply device which the input device 14 has designated as the main component supply device.

Further, the controller 50 is connected to a warning device 16 and outputs an alert signal or representation when the warning device 16 detects an abnormal state that there arises a difficulty against the production such as, e.g., being short of components or the like. The warning device 16 includes LEDs (Light Emitting Diodes) or ramps and informs the worker as to the electronic component mounting apparatus MA falling in the abnormal state by turning them on or turning them on and off when having input thereto a signal indicative of the abnormal state. At the same time, the warning device 16 displays on a display monitor 15 a brief statement or message concerning the detail of the abnormal state such as, for example, “Main Component Supply Device is short of Components.” Thus, the worker can be notified as to the shortage of th components at th main component supply device, in a modified form the embodiment, a dedicated LED or ramp may be provided for generating an alert when the main component supply device runs short of the components.

In addition, the controller 50 is connected with the communication unit 18. Where plural electronic component mounting apparatus MA are installed including one described above, the communication unit 18 is used to exchange the foregoing data with those of other electronic component mounting apparatus MA.

The operation of the electronic component mounting apparatus MA as constructed above, in mounting the electronic components on the circuit boards (S) will be described hereafter. First of all, in advance of the operation start, the worker manipulates the input device 14 to input a scheduled production number, date on the electronic components to be mounted on the board (S), and board data such as the board dimension, the coordinates of on-board targets positions on which the electronic components are to be mounted, and the like. The worker further inputs a main/secondary device designation command so that either one of the component supply devices 31, 32 is designated as the main component supply device which plays the primary role in supplying the electronic components, and so that the other component supply device is designated as the secondary component supply device which supplies the electronic components only when the main component supply device falls short of the electronic components. The microcomputer of the controller 50 makes the memory unit 17 store the input data and the identification data of the component supply devices which have been designated respectively as the main and secondary components supply devices.

As shown in FIG. 1, in this particular embodiment, the first guide rail 21 fixed close to the component supply device 31 is set as a reference guide rail, and the component supply device 31 arranged by the side of the reference guide rail 21 is designated as the main component supply device, while the other component supply device 32 is designated as the secondary component supply device. Or, the component supply device 31 install d closer to a component rack 60 is designated as the main component supply device and the remaining one is designated as the secondary component supply device.

When a mounting start switch (not shown) is turned on by the worker, the microcomputer of the controller 50 executes the mounting control program shown in FIG. 3. The controller 50 instructs the component supply device 31, which is registered in the memory unit 17 as the main component supply device, that the supply device 31 is designated as the main component supply device, (Step 102) That is, the controller 50 in this particular instance designates the component supply device 31 as the main supply device. Then, the controller 50 controls the guide rail position adjusting device 24 to move the movable guide rail 22 to a predetermined position, whereby the width of the transfer way of the board transfer device 20 (i.e., the distance between the guide rails 21 and 22) is automatically adjusted to the width (as was input in advance) of the board (S) on which the electronic components are to be mounted. (Step 104)

Upon completion of this setting, the controller 50 controls the board transfer device 20 to load and advance a circuit board (S) arriving at the entrance of the board transfer device 20, to a predetermined position and fixedly position thereat by the clamping device 23. (Step 106) Then, the controller 50 controls the component mounting device 40 so that the same picks up one or more electronic components from the component supply device 31 having been designated as the main component supply device and mounts the picked-up electronic components successively on one or more target positions on the circuit board. (Stop 108)

Further, before the component mounting device 40 mounts the electronic components on the board (S) after picking up the components, the controller 50 detects whether or not, the picked-up electronic components have been held onto the suction nozzles 42. This makes it possible to judge whether or not, the main component supply device 31 in this instance falls short of the components. (Step 110) More specifically, th controller 50 judges whether the picked-up electronic components are all present or not, based on the image data which is input from the component holding state monitor camera 13 to show the state of the electronic components being held on the suction nozzles 42. If the controller 50 judges at least twice in succession that there is not any electronic component present when the electronic components are taken out in succession from any identical cassette-type feeder 31b, it judges that the cassette-type feeder 31b or the component supply device 31 fall short of the electronic components.

As long as the main component supply device 31 is not short of the electronic components and as long as the number of products has not reached the scheduled production number, the controller 50 repetitively executes the processing at Steps 106 to 112 to continue the production of the boards. Finally, as the number of products reaches the scheduled production number, the controller 50 controls the electronic component mounting apparatus MA to terminate the production of the boards. (Steps 112, 114)

When the supply of the electronic components from the main component supply device 31 is discontinued during the mounting operation onto a circuit board (S), the controller 50 controls the warning device 16 to inform the worker of the component shortage at the main component supply device 31. (Step 116) Thereafter, the controller 50 controls the component mounting device 40 to terminate picking up the electronic components from the main component supply device 31 (Step 118), and instead, to take or pick up the electronic components from the other component supply device 32 having been designated as the secondary component supply device, and to mount the picked-up components on target positions on the circuit board. (Step 120)

The worker who has been informed of the component shortage at the main component supply device 31 removes the same together with the table 33 therefor from the base frame 10. The worker then charges or replenishes the main component supply device 31 with the electronic components, and upon completion of this replenishment, again attaches the main component supply device 31 together with the table 33 to the base frame 10.

While the worker performs the replenishment of the electronic components, the non-attaching or removal state signal is input from the supply device attaching detection sensor 11 for the supply device 31 to the controller 50. In response to the removal state signal, the controller 50 controls the component mounting device 40 to pick up electronic components from the other component supply device 32 having been designated as the secondary component supply device and to mount the picked-up electronic components at the target positions on the board. (Steps 120 and 122)

When the component supply device 31 with which the replenishment of the electronic components has been completed is attached again to the base frame 10, a signal indicative of the attaching state is input from the attaching detection sensor 11 for the component supply device 31 to the controller 50. In response to this signal, the controller 60 controls the component mounting device 40 to discontinue picking up the electronic components from the secondary component supply device 32 (Steps 122 and 124), and instead, to resume picking up the electronic components from the component supply device 31 having been designated as the main component supply device, and to mount the picked-up electronic components at the target positions on the circuit board. (Step 108)

In this embodiment, as understood from the foregoing description, the main component supply device which plays the primary role to supply the electronic components is assigned to one (i.e., 31) of the component supply devices 31, 32 which is arranged close to the first guide rail 21 serving as the reference guide rail or which is arranged closer to the component rack 60 storing the electronic components. The other component supply device 32 is assigned as the secondary component supply device which supplies the electronic components while the supply of the components from the main component supply device 31 is halt d. Accordingly, during the ordinary mounting operation, the electronic components are supplied from the main component supply device 31, and while the supply of the components form the main component supply device 31 is halted, the electronic components are supplied from the secondary component supply device 32.

When the supply of the components from the main component supply device 31 is discontinued while the electronic component mounting apparatus MA is performing the mounting operation by being supplied with the electronic components from the main component supply device 31, the same is caused to stop the supplying operation, and an automatic switchover is carried out to make the secondary component supply device 32 start the supplying operation. During the secondary component supply device 32 in operation, the worker charges or replenishes the main components supply device 31 with the electronic components. In replenishing the electronic components, the worker is not required to replenish the electronic components into both of the supply devices 31, 32. That is, he or she is only required to perform the replenishment into one of the supply devices 31, 32, i.e., into the main component supply device 31. Accordingly, it can be realized to improve the work in replenishing the electronic components. In addition, since the main component supply device 31 is located close to the reference guide rail (i.e., the first guide rail 21) or close to the component rack 60, it becomes unnecessary to fetch the electronic components from a remote location, so that the time and labor can be considerably reduced in replenishing the electronic components.

Further, in the aforementioned embodiment, the main component supply device 31 has set therein the electronic components which are necessary to be mounted on the first boards (S1), and the secondary component supply device 32 has also set therein the same electronic components as those set in the main component supply device 31 which are necessary to be mounted on the first boards (S1). And, mounting the electronic components on the first boards (S1) is carried out by supplying them from the main component supply device 31 during th ordinary mounting operation, but from the secondary component supply device 32 while the supply of the components from the main component supply device 31 is discontinued. That is, when the component supply from the main component supply device 31 is discontinued during mounting the electronic components from the main component supply device 31 on the first boards (S1), the electronic component mounting apparatus MA stops the supply from the main component supply device 31 and switches to the supply from the secondary component supply device 32 to continue mounting the electronic components on the first boards (S1). During this time, the worker replenishes the main component supply device 31 with the electronic components. After replenishment, the electronic component mounting apparatus MA stops the supply from the secondary component supply device 32 and switches to the supply again from the main component supply device 31 to continue mounting the electronic components on the first boards (S1). As a consequence, the production of plural boards (S) of the same kind can be continued without being halted due to replenishment of the electronic components.

(Second Embodiment)

Although the foregoing embodiment is directed to the application wherein a plurality of component mounting boards of the same kind are produced, the second embodiment may be practiced in such a way that two kinds of boards (e.g., S1, S2) which are different in the kinds of the electronic components to be mounted thereon are produced with the first boards (S1) being considerably larger in the number of products than the second boards (S2). In this second embodiment, electronic components to be mounted on the first boards (S1) are set in the cassette-type feeders 31a of the component supply device 31 assigned as the main component supply device, while electronic components to be mounted on the second boards (S2) and different from those for the first boards (S1) are set in the cassette-type feeders 32a of the component supply device 32 assigned as the secondary component supply device. Other constructions in the second embodiment are the same as those described above and therefore, are omitted from being described.

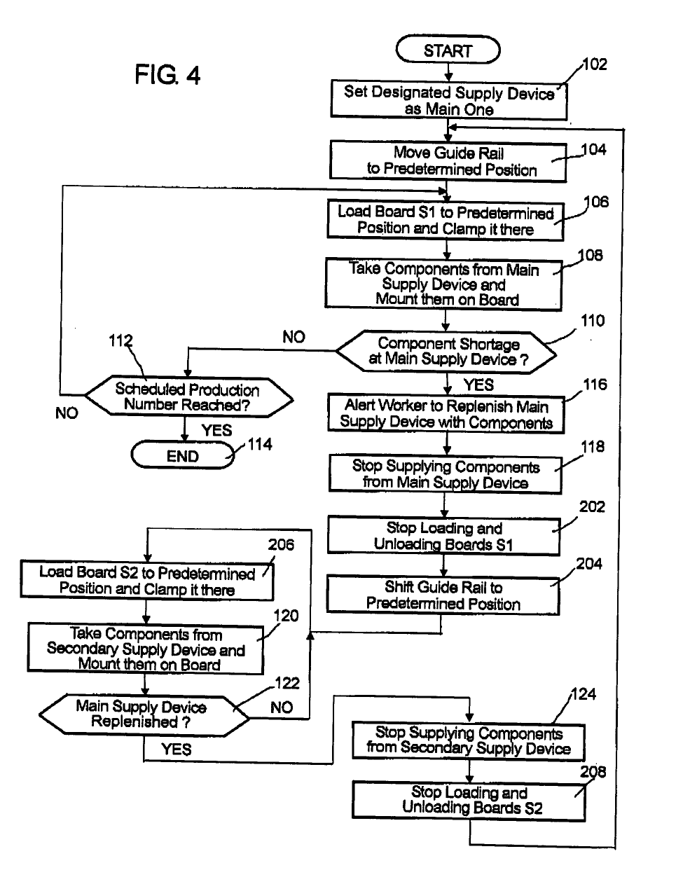

The operation of the second embodiment as constructed above in mounting the electronic components on the boards will be described hereafter with reference to FIG. 4. The controller 50 executes a mounting control program represented by the flow chart shown in FIG. 4 and controls mounting the electronic components on the first and second boards S1, S2. The second embodiment is the same as the first embodiment in the basic control, but is different from the latter in the following respect. That is, during the ordinary mounting operation, the first boards (S1) are produced by mounting thereon the electronic components from the main component supply device (31). On the other hand, while the component supply from the main component supply device (31) is discontinued, the second boards (S2) are produced instead.

More specifically, when the component supply from the main component supply device 31 is discontinued during the operation for mounting on the first boards (S1) the electronic components from the main component supply device 31, the controller 50 informs the worker of that effect or purport and discontinues the supply from the main component supply device 31 while stopping the further loading/unloading of the first boards (S1) after discharging the board (S1) under process or shunting the same into, if any, a shunting place. (Steps 116, 118, 202) Then, the controller 50 moves the guide rail 22 to the predetermined position in the same manner as the processing at Step 104 thereby to set the transfer way width of the board transfer device 20 to the width of the second board (S2) (Step 204), and then, advances a second board (S2) to the predetermined position in the same manner as the processing at Step 106 thereby to fixedly position the second board (S2) thereat. (Step 206) Subsequently, until the replenishment of the electronic components to the main component supply device 31 is completed, the controller 50 repetitively executes the processing including Steps 206 and 120 thereby to mount the components on the second boards (S2). Upon completion of the replenishment, the controller 50 stops the supply from the secondary component supply device 32, stops further loading and unloading the second boards (S2) (Steps 124, 208) and resumes the production (component mounting operation) of the first boards (S1) by repetitively executing the processing including Step 108 to Step 112.

Accordingly, in producing the boards of two kinds (i.e., first and second boards S1, S2), the mounting on the second boards (S2) can be carried out by utilizing the time period in which the electronic components to be mounted on the first board (S1) are replenished to the main component supply device 31, so that the electronic component mounting apparatus MA can effectively be utilized without discontinuing the mounting operation due to such replenishment of the electronic components. Especially, where the first boards (S1) are considerably larger in production volume than the second boards (S2), it becomes possible to effectively produce (i.e., perform the mounting operations on) the boards (S1, S2) of the two kinds.

(Third Embodiment)

Further, in the aforementioned second embodiment, the change of the productions in the first and second boards is made taking as a turning point the shortage of the components in the main component supply device 31 which supplies the components to be mounted on the first boards (S1). On the contrary, the change to the production of the second boards (S2) may be made taking as a turning point the completion in the production of a scheduled number of the first boards (S1) designated by a production schedule, as described in the following third embodiment. In this third embodiment, data on the production schedule is stored in the memory unit 17 of the electronic component mounting apparatus MA or in a memory unit of a superior host computer (both not shown) which is enabled to communicate with the electronic component mounting apparatus MA. Herein, the “production schedule” means information, data or a program for designating the kind and production volume of the boards to be produced in the time sequence as planned. For instance, the production schedule may be made in such a way to produce a hundred pieces of the first boards (S1) at the beginning, to produce five pieces of the second boards (S2) then and to produce two hundred pieces of the first boards (S1) thereafter.

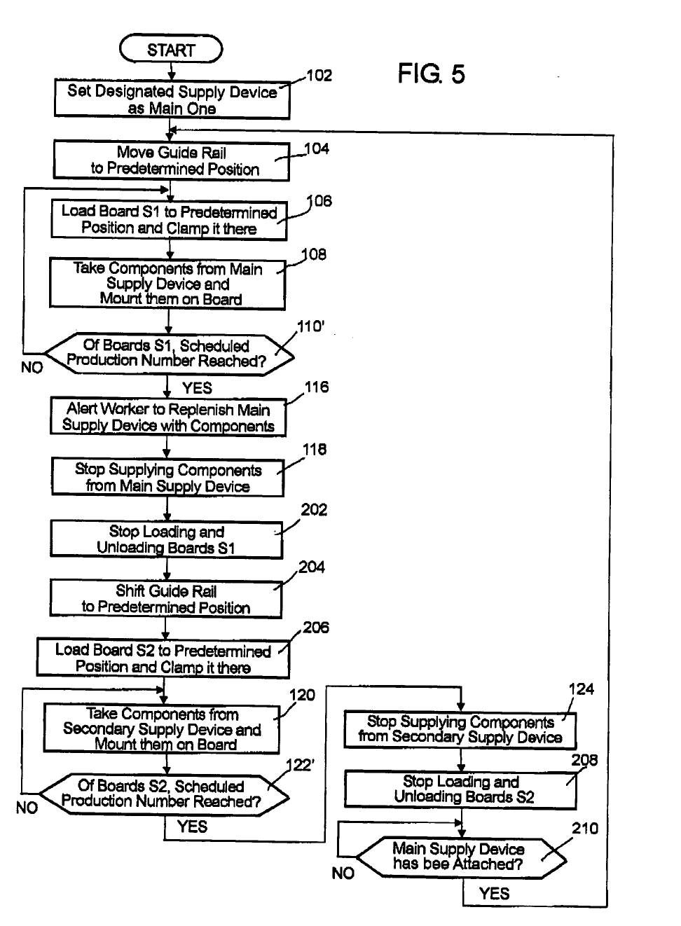

The component mounting operation in the third embodiment is carried out by executing a mounting control program represented by a flow chart sown in FIG. 5. The control in this third embodiment is basically the same as that in the second embodiment shown in FIG. 4, but is different from that in the second embodiment shown in FIG. 4 in the following respect. That is, the production schedule is taken as a turning point in changing the production of the first boards (S1), which is performed with the electronic components being supplied from the main component supply device 31, with the production of the second boards (S2) which is performed with the electronic components being supplied from the secondary component supply device 32.

More specifically, the controller 50 executes the mounting control program by reference to the production schedule stored in the memory unit 17. When the production of the scheduled number of the first boards (S1) is completed, the controller 50 informs the worker of that purport, stops supplying the components from the main component supply device 31, and stops further loading and unloading the first boards (S1). (Steps 110′, 116, 118, 202) At this time, although the components which make it possible to continue the production of the first boards (S1) remain stored in the main component supply device 31, it is not certain that the components of the number or volume which meets the next production in a scheduled number of the first boards (S1) remain stored therein. Therefore, the worker checks the number of the components remaining stored and unless the components of the number which corresponds to the number scheduled to be made in the next production of the first boards (S1) do not remain stored therein, works to replenish the main component supply device 31 with the components.

Subsequently, the controller 50 moves th guide rail 22 to the predetermined position in the same way as the processing at Step 104, sets the transfer way width of the board transfer device 20 to the width of the second boards (S2) (Step 204), and advances a first second board (S2) to the predetermined position in the same way as the processing at Step 106 thereby to fixedly position thereat. (Step 206) Then, the controller 50 repetitively executes the processing at Steps 120 and 122′ until the production of the second boards (S2) reaches the scheduled number. Upon completion of the production of the scheduled number, the controller 50 stops the supply from the secondary component supply device 32, stops further loading and unloading successive second boards (S2) (Steps 124 and 208), and judges whether or not, the main component supply device 31 has been attached onto the electronic component mounting apparatus MA (Step 210). When such attaching work is confirmed to have been completed, the controller 50 resumes the production (component mounting operation) of the first boards (S1) by repetitively executing th processing including Steps 104 to 110′.

(Fourth Embodiment)

Moreover, the present invention may be applied to the case that boards of the same kind each having a considerably many components to be mounted thereon are produced in a large volume. In this fourth embodiment, of the electronic components necessary to be mounted on the first boards (S1), those used in higher frequencies are set in the respective cassette-type feeders 31a of the component supply device 31 acting as the main component supply device, while those used in lower frequencies and different from the electronic components set in the main component supply device 31 are set in the respective cassette-type feeders 32a of th component supply device 32 acting as the secondary component supply device Other respects in construction are the same as those described in the aforementioned embodiments and hence, are omitted from being described.

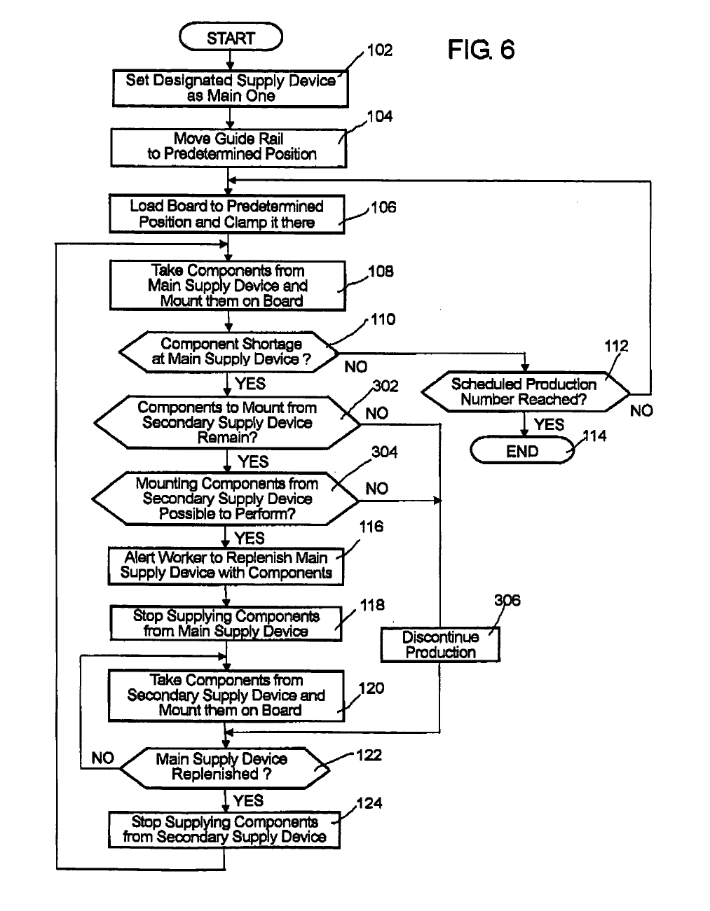

The component mounting operation in the fourth embodiment as constructed above will be described hereafter with reference to FIG. 6. The controller 50 executes a mounting control program corresponding to the flow chart shown in FIG. 6 and controls the mounting of the electronic components on the first boards (S1). The fourth embodiment is the same as the foregoing embodiments in the basic control, but is different from foregoing embodiments in the following respect. That is, during the ordinary mounting operation, the first boards (S1) are produced by mounting thereon the electronic components used in the higher frequencies, from the main component supply device 31. On the other hand, while the component supply from the main component supply device 31 is discontinued, the electronic components used in the lower frequencies are supplied from the secondary component supply device 32 thereby to produce (i.e., to mount the components on) the first boards (S1).

More specifically, when the component supply from the main component supply device 31 is discontinued during the operation for mounting on the first boards (S1) the electronic components from the main component supply device 31, it is judged whether or not, the electronic components have been stored in the secondary component supply device 32 and whether or not, such components are mountable to meet their conditions for mounting. If such components are mountable, the controller 50 informs the worker of that purport, and stops the supply from the main component supply device 31. (Steps 110, 302, 304, 116 and 118) Then, the controller 50 repetitively executes the processing at Step 120 and the processing at 122, so that the electronic components are supplied from the secondary component supply device 32 and are mounted on the first boards (S1). When the worker completes replenishing the main component supply device 31 with the larger-frequency electronic components, the controller 50 stops the supply from the secondary component supply device 32 (Step 124) and instead, resumes supplying the electronic components from the main component supply device 31, so that th production (component mounting operation) of th first boards (S1) is restarted by repetitively executing the processing including Steps 106 to Step 112).

When the main component supply device 31 falls short of the components during the operation for mounting the electronic components from the main component supply device 31 on the first boards (S1), and when the electronic components, if any in the secondary component supply device 32, do not satisfy their conditions for mounting and hence, not mountable, or when there is no electronic component to take out for mounting, the production of the component mounting boards (S1) is discontinued until replenishing the main component supply device 31 with the components is completed. (Steps 302, 304, 306 and 122)

Accordingly, where the boards of a single kind having plural components to be mounted thereon are to be produced in a large volume, the components used in lower frequencies can be mounted on the boards while the worker replenishes the main component supply device 31 with the components used in the higher frequencies. Thus, the production of the component mounting boards (e.g., S1) can be effectively performed without being discontinued by the component replenishment.

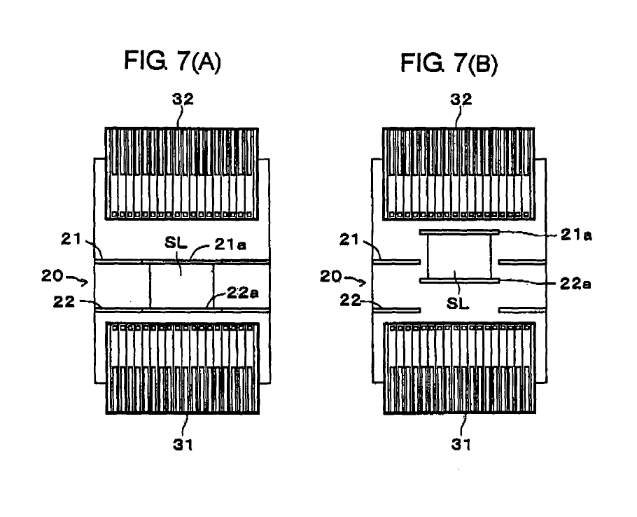

In addition, the present invention may be practiced in various modified form, some of which will typically be described hereafter. For example, in the case of mounting electronic components on relatively small boards (SL), while th component supply from the main component supply device 31 is discontinued, th mounting operation may be performed with the board transfer device 20 (i.e., the board transfer way) being shifted close to the secondary component supply device (the component supply device 32) for supplying the electronic components, as shown in FIG. 7(B). In this case, the board transfer device 20 may take a configuration that the center portions 21a, 22a of the guide rails 21, 22 are separated to be bodily shifted close to the secondary supply device 32, or that the guide rails 21, 22 may as a whole be shifted close to the secondary supply device 32 without making the center portions 21a, 22a thereof separated therefrom. In this modified form, when the main component supply device is in service to supply the electronic components for mounting on the boards, the guide rails 21, 22 or the center portions 21a, 22a of the board transfer device 20 may be at the home position close to the main component supply device 31, as shown in FIG. 7(A).

With this modified form, the distance from the secondary component supply device 32 to the board (SL) can be shortened for the supply of the electronic components from the secondary component supply device 32 to the board (SL), so that the throughput of the electronic components mounting apparatus MA can be increased.

Further, in the foregoing embodiments, the component supply devices 31, 32 are designated respectively as the main and secondary component supply devices. However, the component supply devices 31, 32 may be designated respectively as the secondary and main ones.

Also, although in the foregoing embodiment, the position of the guide rail 22 only is adjustable by the guide rail position adjusting device 24, the positions of the both guide rails 21, 22 may be adjustable by the guide rail position adjusting device 24. Moreover, the position adjustments of the guide rails 21, 22 may be effected manually.

It is to be noted that although the cause for the halting the component supply from the component supply device 31 (or 32) derives from the component shortage in the foregoing embodiment, such cause may derives from one or more other states in operation of the electronic component mounting apparatus MA As described hereinabove, in the first embodiment of the present invention, when the component supply from the main component supply device 31 is discontinued while the electronic component mounting apparatus MA is in operation to mount the electronic components from the main component supply device 31, an automatic switching control is performed to halt the supply from the main component supply device 31 and instead, to start the supply from the secondary component supply device 32, during which the worker is enabled to replenish th main component supply device 31 with the components. In this replenishment, the worker is required only to replenish the main component supply device, i.e., one of th component supply devices 31, 32, but not required to replenish both of the component supply devices 31, 32, as is the case in the prior art. Accordingly, the worker can be relieved of a heavy work in the component replenishment on the both of the component supply devices 31, 32, and the work in replenishing the components can be improved.

In the embodiment described above, a board transfer device 20 is provided with the pair of board guide rails 21, 22 one of which serves as a reference guide rail, and one (e.g., 31) of the component supply devices arranged close to the reference guide rail 21 is designated as the main component supply device while the other component supply device 32 is designated as the secondary component supply device, so that the components are supplied from the main component supply device 31 during the ordinary mounting operation, but from the secondary component supply device 32 when the component supply from the main component supply device 31 is discontinued. Thus, the switching from the main component supply device 31 to the secondary component supply device 32 is automatically performed, and during the mounting operation using the components from the secondary component supply device 32, the worker is enabled to charge or replenish the main component supply device 31 with the electronic components. In particular, since the main component supply device 31 is arranged close to the reference guide rail 21 of the board guide rails 21, 22, the main component supply device 31 is arranged to come closer to the board on the transfer device 20 than the secondary component supply device 32. As a result, the mounting of the components from the main component supply device 31 can be done speedy, so that the efficiency or productivity in the mounting operation can be enhanced.

In the embodiment described above, a component rack 60 is provided for storing components to be replenished to the component supply devices 31, 32, one (e.g., 31) of these devices which is arranged close to th component rack 80 is designated as the main component supply device and the other component supply device 32 is designated as the secondary component supply device, so that the components are supplied from the main component supply device 31 during the ordinary mounting operation, but from the secondary component supply device 32 when the component supply from the main component supply device 31 is discontinued. Thus, the worker is required only to replenish the main component supply device, i.e., one of the component supply devices, but not required to replenish both of the component supply devices, as is the case in the prior art. In particular, since the main component supply device 31 is arranged close to the component rack 60, the time and labor for fetching the component from a remote location can be reduced, so that the work to replenish the component can be improved.

In the aforementioned first embodiment, the same components which are necessary to be mounted on first boards (S1) are set in the main and secondary component supply devices 31, 32, and after the component supply from the main component supply device 31 is discontinued, the mounting on the first boards (S1) is continued using the component from the secondary component supply device 32. Thus, the production of the boards of a single kind (e.g., S1) in a large volume can be continued without being interrupted by replenishing the main component supply device 31 with the components.

In the second embodiment described above, the main component supply device 31 has set therein components which are necessary to be mounted on th first boards (S1) while the secondary component supply device 32 has set therein components which are necessary to be mounted on the second boards (S2) different from the first boards (S1). When the component supply from the main component supply device 31 is discontinued, the mounting of the components on the first boards (S1) is halted, and the mounting on the second boards (S2) is initiated instead using the components from the second component supply device 32. Thus, the mounting on the second boards (S2) can be carried out by utilizing the time period in which the components to be mounted on the first board (S1) are replenished to the main component supply device 31, so that the electronic component mounting apparatus MA can effectively be utilized without discontinuing the mounting operation due to such replenishment of the electronic components.

In the third embodiment described above, the main component supply device 31 has set therein components which are necessary to be mounted on the first boards (S1) and wherein the secondary component supply device 32 has set therein components which are necessary to be mounted on the second boards (S2) different from the first boards (S1). When it is confirmed by reference to a production schedule that the production of the first boards (S1) to a scheduled number has been completed, the production of the first boards (S1) is terminated, and instead, the production of the second boards (S2) is initiated. Thus, the switching from the production of the first boards (S1) to the production of the second boards (S2) can be automatically performed, and it becomes possible to do the component replenishing work the most effectively in accordance with the production schedule.

In the fourth embodiment described above, the main component supply device 31 has set therein components which are necessary to be mounted on the first boards (e.g., S1) and which are used in higher frequencies, while the secondary component supply device 32 has set therein components which are necessary to be mounted on the first boards (S1) and which are used in lower frequencies differently from those set in the main component supply device 31. Thus, the boards of the single kind (e.g., S1) can be produced by supplying the components used in the higher frequencies from the main component supply device 31 during the ordinary mounting operation, and when the supply from the main component supply device 31 is discontinued, by supplying the components used in the lower frequencies from the secondary component supply device 32. During the mounting operation using the lower use frequency components from the secondary component supply device 32, the worker is enabled to replenish the main component supply device 31 with the higher use frequency components. Upon completion of the replenishing work, the supply of the lower use frequency components from the secondary component supply device 32 is discontinued, and instead, the supply of the higher use frequency components from the main component supply device 31 is resumed. Accordingly, where the boards of the same kind each having many components to be mounted thereon are to be produced in a large volume, the lower use frequency components can be mounted while the worker replenishes the main component supply device 31 with the higher use frequency components. Therefore, the interruption of the production due to the component replenishment can be avoided, so that the productivity of the boards of the single kind can be enhanced.

In a modified form of the present invention, the board transfer device 20 is moved close to the secondary component supply device 32 in supplying the components from the secondary component supply device 32 after the component supply from the main component supply device 31 is discontinued. Thus, where relatively small boards (SL) are to be produced, the components can be supplied via shorter distances from the secondary component supply device 32 for mounting on the small boards (SL), so that the throughput of the electronic components mounting apparatus MA can be enhanced.

Obviously, numerous modifications and variations of the present invention are possible in light of the above teachings. It is therefore to be understood that within the scope of the appended claims, the present invention may be practiced otherwise than as specifically described herein.

What is claimed is:

1. An electronic component mounting method of supplying electronic components from both of a pair of component supply devices which are arranged with a board transfer device therebetween and of mounting said components on circuit boards transferred by said board transfer device, said method comprising the steps of:
designating one of said component supply devices as main component supply device for primarily supplying said components and the other component supply device as secondary component supply device for supplying said components while the component supply from said main component supply device is discontinued;
supplying said components from said main component supply device during an ordinary mounting operation; and
when the component supply from said main component supply device is discontinued, performing a switching control so that said components are supplied from said secondary component supply device.

2. An electronic component mounting apparatus wherein a board transfer device is provided for transferring circuit boards and wherein a pair of component supply devices are arranged with said board transfer device therebetween for supplying electronic components to be mounted on said boards, said apparatus comprising:
designation means for designating one of said component supply devices as main component supply device for primarily supplying said components and the other component supply device as secondary component supply device for supplying said components while the component supply from said main component supply device is discontinued; and
switching control means for performing a switching control so that said components are supplied from said main component supply device during an ordinary mounting operation, but from said secondary component supply device when the component supply from said main component supply device is discontinued.

3. An electronic component mounting apparatus wherein a board transfer device is provided for transferring circuit boards along a pair of board guide rails on of which serves as reference guide rail and wherein a pair of component supply devices are arranged with said board transfer device therebetween for supplying electronic components to be mounted on said boards, said apparatus comprising:
designation means for designating one of said component supply devices arranged close to said reference guide rail as main component supply device for primarily supplying said components and the other component supply device as secondary component supply device for supplying said components while the component supply from said main component supply device is discontinued; and
switching control means for performing a switching control so that said components are supplied from said main component supply device during an ordinary mounting operation, but from said secondary component supply device when the component supply from said main component supply device is discontinued.

4. An electronic component mounting apparatus wherein a board transfer device is provided for transferring circuit boards and wherein a pair of component supply devices are arranged with said board transfer device therebetween for supplying electronic components to be mounted on said boards, said apparatus comprising:
a component rack for storing said components to be replenished to said component supply devices;
designation means for designating one of said component supply devices arranged close to said component rack as main component supply device for primarily supplying said components and the other component supply device as secondary component supply device for supplying said components while th component supply from said main component supply device is discontinued; and
switching control means for performing a switching control so that said components are supplied from said main component supply device during an ordinary mounting operation, but from said secondary component supply device when the component supply from said main component supply device is discontinued.

5. The apparatus as claimed in claim 2, wherein said main component supply device has set therein electronic components which are necessary to be mounted on first boards and wherein said secondary component supply device has set therein electronic components which are necessary to be mounted on said first boards and which are the same as those set in said main component supply device, said apparatus further comprising:
mounting means for mounting said components on said first boards by supplying said components from said main component supply device during said ordinary mounting operation, but from said secondary component supply device when the component supply from said main component supply device is discontinued.

6. The apparatus as claimed in claim 2, wherein said main component supply device has set therein electronic components which are necessary to be mounted on first boards and wherein said secondary component supply device has set therein electronic components which are necessary to be mounted on second boards different from said first boards, said apparatus further comprising:
mounting means for mounting said components on said first boards from said main component supply device during said ordinary mounting operation, but mounting said components on said second boards from said secondary component supply device when the component supply from said main component supply device is discontinued.

7. The apparatus as claimed in claim 2, wherein said main component supply device has set therein electronic components which are necessary to be mounted on first boards and wherein said secondary component supply device has set therein electronic components which are necessary to be mounted on second boards different from said first boards, said apparatus further comprising:
mounting means for terminating the production of said first boards when it is confirmed by reference to a production schedule that the production of said first boards to a scheduled number has been completed, and instead, for initiating the production of said second boards.

8. The apparatus as claimed in claim 2, wherein said main component supply device has set therein electronic components which are necessary to be mounted on first boards and which are used in higher frequencies and wherein said secondary component supply device has set therein electronic components which are necessary to be mounted on said first boards and which are used in lower frequencies differently from those set in said main component supply device.

9. The apparatus as set forth in claim 2, further comprising:
moving means for moving said board transfer device close to said secondary component supply device in supplying said components from said secondary component supply device after the component supply from said main component supply device is discontinued.

10. An electronic component mounting program for transferring circuit boards along a pair of board guide rails of a board transfer device and for supplying electronic components from a pair of component supply devices, arranged with said board transfer device therebetween, thereby to mount said components on said boards, said program comprising the steps of:
designating one of said component supply devices arranged close to a reference guide rail of said pair of board guide rails as main component supply device for primarily supplying said components and the other component supply device as secondary component supply device for supplying said components while the component supply from said main component supply device is discontinued; and
performing a switching control so that said components are supplied from said main component supply device during an ordinary mounting operation, but from said secondary component supply device when the component supply from said main component supply device is discontinued.
